(19) United States
(12) Patent Application Publication
(10) Pub. No.: US 2004/0101003 A1
(43) Pub. Date: May 27, 2004

(54) Peltier cooler and semiconductor laser module

(76) Inventor: Hiroyasu Torazawa, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/414,404

(22) Filed: Apr. 16, 2003

(30) Foreign Application Priority Data
Nov. 25, 2002 (JP) P2002-340208

(51) Int. Cl. H01S 3/04; H01S 5/00

(52) U.S. Cl. 372/34; 372/36; 372/43

(57) ABSTRACT

A peltier cooler includes a plurality of P type peltier elements; a plurality of N type peltier elements; a plurality of electrodes for connecting the P type peltier element and the N type peltier element; and two boards for sandwiching the P type peltier element and the N type peltier element. In the peltier, the board has cylindrical curve surface.

### BACKGROUND OF THE INVENTION

1. Field of the Invention

The present invention relates to a peltier cooler applies in temperature control of semiconductor laser module or the like, and relates to the semiconductor laser module including the peltier cooler.

2. Description of the Related Art

A peltier cooler, as stated in the Japanese patent publication 10-190141 severing as a patent document, is used for temperature control in semiconductor laser module.

In general, the semiconductor laser module is formed, by installing a semiconductor laser element, a receiving light element and an optical system into a metal package. The semiconductor laser element occurs laser light having a predetermined wavelength, by making the electric current flow. The wavelength depends upon the temperature, and changes with the change of the temperature in circumference. Further, in the semiconductor laser element, light output also changes with the change of the temperature because of the change of operating power source or self-heating or the like.

With respect to such semiconductor laser element, because its light output and its wavelength strongly depends upon the temperature, the semiconductor laser module generally includes a themistor element and a peltier cooler for temperature control.

In the case that the temperature of the semiconductor laser element rises by heat occurred in emitting light by making the electric current flow in the semiconductor laser element, the themistor element senses the rose quantity of temperature and changes the resistance, then the peltier cooler is operated to cool for controlling the temperature. Thus, a standard temperature can be kept.

FIG. 9 is squint-eyed diagram showing a previous peltier cooler. Though the peltier cooler is stated in the above-mentioned patent document, but not clearly described in detail structure. Thereby, the following, referring to the FIG. 9, the structure will be explained.

In general, the peltier cooler used for temperature control of the semiconductor laser module, has a such structure as sandwich shape by using two flat boards 4, 4. In between the two flat boards 4, 4, a plurality of P type peltier elements 1 and a plurality of N type peltier elements 2 are placed alternately, and a plurality of electrodes 3 are provided for respectively connecting the P type peltier element 1 and N type peltier element 2.

These electrodes 3 are formed on the flat board 4 and enable to alternately connect the two kinds of electrodes i.e. the P type peltier element 1 and N type peltier element 2 in series. On the electrode 3 placed at end of the flat board 4, a lead 5 is connected for external connection.

The peltier cooler having such structure as described above, by using peltier effect, when electric current flows, enables to respectively make the one surface of the flat board 4 become a cooling surface and the other surface of the flat board 4 become a heating surface. Of course, if making the electric current oppositely flow, the cooling and the heating surfaces will be reversed.

Such functions with cooling and heating of the peltier cooler are used for temperature control in the semiconductor laser module. In this case, the resistance of the themistor element is used for converting the standard temperature into resistance value.

However, in this case that the semiconductor laser module is cylindrical shape such as can type or coaxial type, if using such peltier cooler having the flat board 4, because of the shape of the flat board, it become impossible to perform a corresponding control. That is, when such peltier cooler is applied to the semiconductor laser module, because the usable area becomes small with respect to the surface to be used of the flat board, there is such problem that it is impossible to guarantee the temperature control function.

Further, in this case that the semiconductor laser module is a cylindrical package, if using such peltier cooler having the flat board, in fact, it is difficult to install the peltier cooler into the package.

### SUMMARY OF THE INVENTION

In view of the above, it is an object of the present invention to provide a peltier cooler capable of applying to semiconductor laser module showing cylindrical shape, and to provide a semiconductor laser module which has the peltier cooler and enables to certainly perform temperature control.

According to a first aspect of the present invention, there is provided a peltier cooler, including a plurality of P type peltier elements; a plurality of N type peltier elements; a plurality of electrodes for connecting the P type peltier element and the N type peltier element; and two boards for sandwiching the P type peltier element and the N type peltier element. In the peltier cooler, the board has cylindrical curve surface.

Severing as the peltier cooler, it may more include a plurality of supporting sections formed on the board for supporting the either of the P type peltier element, the N type peltier element.

Further, Severing as the peltier cooler, it may more include a plurality of level portions formed on the electrode and fixed on the supporting section.

According to a second aspect of the present invention, there is provided a semiconductor laser module including at least one peltier cooler.

In the semiconductor laser module, the peltier cooler compeises a plurality of P type peltier elements; a plurality of N type peltier elements; a plurality of electrodes for connecting the P type peltier element and the N type peltier element; and two boards for sandwiching the P type peltier element and the N type peltier element. In the peltier cooler, the board has cylindrical curve surface.

Also, in the semiconductor laser module, the peltier cooler may more comprise a plurality of supporting sections formed on the board for supporting the either of the P type peltier element, the N type peltier element.

Further, the peltier cooler may more comprise a plurality of level portions formed on the electrode and fixed on the supporting section.

Severing as the semiconductor laser module, it may more include a metal package. In this case, a plurality of the peltier coolers may be installed and joined on the outside surface of the metal package.

Moreover, the semiconductor laser module may be can type or coaxial type.

### BRIEF DESCRIPTION OF THE DRAWINGS

The above and other objects, advantages and features of the present invention will be more apparent from the following description taken in conjunction with the accompanying drawings in which:

FIG. 1 is a squint-eyed diagram illustrating a peltier cooler in first embodiment of the present invention;

FIG. 2 is a partial enlargement of the FIG. 1;

FIG. 3 is a squint-eyed diagram illustrating a peltier cooler in second embodiment of the present invention;

FIG. 4 is a partial enlargement of the FIG. 3;

FIG. 5 is a squint-eyed diagram illustrating a peltier cooler in third embodiment of the present invention;

FIG. 6 is diagram illustrating an example applying the peltier cooler to a semiconductor laser module;

FIG. 7 is diagram illustrating an example applying the peltier cooler to a semiconductor laser module;

FIG. 8 is diagram illustrating a installed state of the peltier cooler installed in a semiconductor laser module; and

FIG. 9 is a squint-eyed diagram illustrating a previous peltier cooler.

### DESCRIPTION OF THE PREFERRED EMBODIMENTS

Best modes of carrying out the present invention will be described in further detail using various embodiments with reference to the accompanying drawings.

### Embodiment

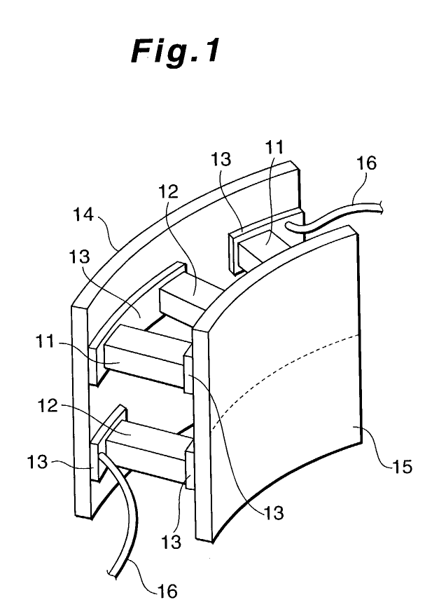

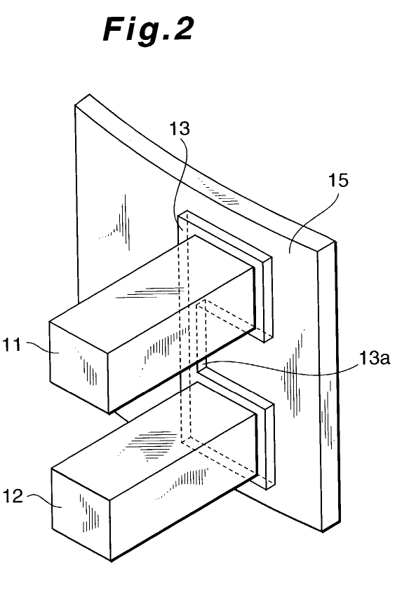

FIG. 1 is a squint-eyed diagram illustrating a peltier cooler in first embodiment of the present invention, and FIG. 2 is a partial enlargement of the FIG. 1. In FIG. 2, the outer board and the electrode do not be shown.

The peltier cooler is constructed from a plurality of P type peltier elements 11, a plurality of N type peltier elements 12, a plurality of electrodes 13, a outer board 14 and a inner board 15.

The outer board 14 and the inner board 15 respectively have cylindrical curve surface, and are placed such as facing each other.

In between the outer board 14 and the inner board 15, these electrodes 13 are respectively formed on the facing surfaces of the outer board 14 or the inner board 15; these P type peltier elements 11 and these N type peltier elements 12 are alternately placed and respectively connected each other in series by the electrode 13. Thus, the peltier cooler is showing such shape as sandwich.

Moreover, on such electrodes 13 respectively placed at the ends of the outer board 14, leads 16 are provided.

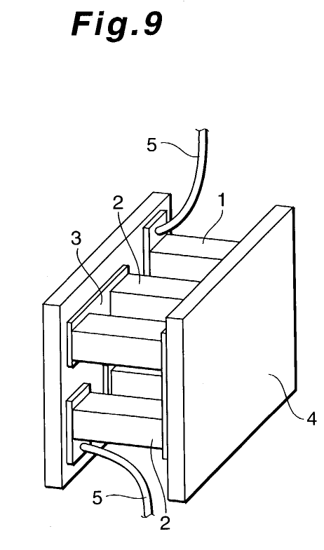

In the first embodiment, as compared with the previous flat boards 1 and 2 shown in FIG. 9, this is a feature that the outer and the inner boards 14 and 15 are respectively having cylindrical curve surfaces.

The boards 14 and 15, as usual, may be made of these materials such as Alumina, Al4N3 etc. by burn-forming means or the like. Then, by using such burn-forming use mould with cylindrical curve surface, the cylindrical curve surface of the board 14 or 15 can be formed easily.

Moreover, on the facing surface of the outer board 14 or the inner board 15, some areas used for forming the electrode 13 can be levelly formed to sever as level portions. Thus, the electrode 13 can be easily formed.

Then, the electrode 13 may be formed on the level portion by metal plating. Also, the electrode 13 may be formed on the level portion by adhesive means, for example, solder or the like.

Moreover, when these level portions do not exist, it is possible to form the electrode 13 according to such shape described as follows.

That is, when the electrode 13 is formed on the outer board 14, it is possible to form one end surface of the electrode 13 into convex cylindrical curve shape in order to make the one end surface contact the facing surface of the outer board 14, and to form other end surface of the electrode 13 into flat shape in order to make the other end surface contact the P type peltier element 11 or the N type peltier element 12.

When the electrode 13 is formed on the inner board 15, it is possible to form one end surface of the electrode 13 into concave cylindrical curve shape in order to make the one end surface contact the facing surface of the inner board 15, and to form other end surface of the electrode 13 into flat shape in order to make the other end surface contact the P type peltier element 11 or the N type peltier element 12.

These electrodes 13, after made according to such shapes, may be glued on the board 14 or 15.

The P type peltier element 11 or the N type peltier element 12 can be glued by solder or the like. The solder may be formed from Sn and Sb, or, Au and Sn, or the like.

Moreover, excepting such electrodes 13 placed at the ends of the outer board 14, the other electrode 13 may include a connection portion 13a shown as FIG. 2 for connecting the P type peltier element 11 or the N type peltier element 12 in series.

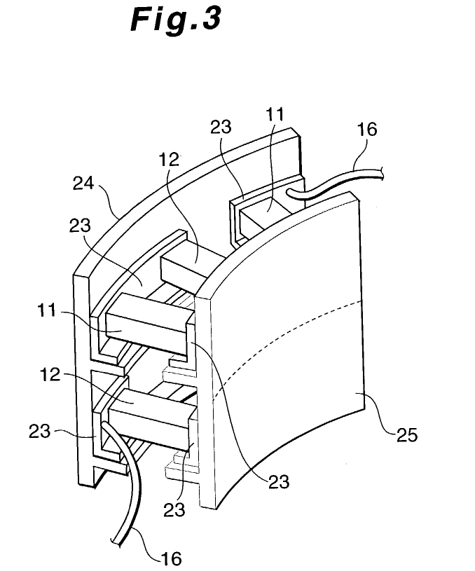

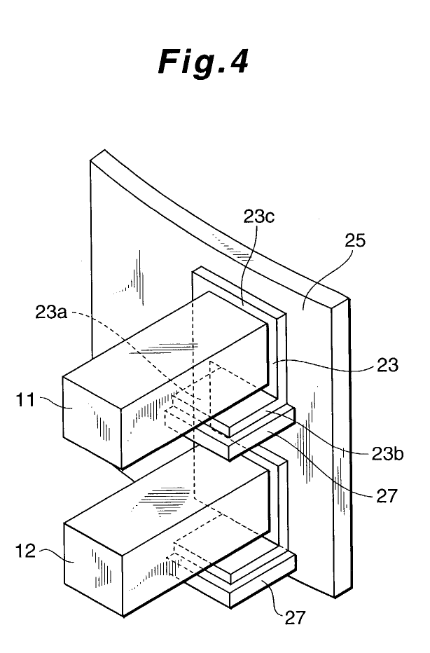

FIG. 3 is a squint-eyed diagram illustrating a peltier cooler in second embodiment of the present invention, and FIG. 4 is a partial enlargement of the FIG.3. In the FIG. 4, the outer board and the electrode do not be shown.

As compared with the first embodiment, the second embodiment has a base structures like that in the first embodiment. However, in the second embodiment, there are a plurality of supporting sections 27 and a plurality of level portion 23b, they are different from the first embodiment.

The supporting section 27 is formed on the facing surface of the outer board 24 or the inner board 25 for supporting the P type peltier element 11 or the N type peltier element 12. Moreover, the supporting section 17 may be formed in a unity with the board 14 or 15 by burn-forming, also, may be separately made of the same material of the board 14 or 15 and be fixed by an adhesive.

The electrode 23, as shown in FIG. 4, excepting a main portion 23c and a connection portion 23a such as the connection section 13a in the first embodiment, more includes a level portion 23b.

The level portion 23b is formed in a unity with the main portion 23c, more is fixed on the supporting section 27 by an adhesive or the like. On the level portion 23b, the P type peltier element 11 or the N type peltier element 12 is glued by solder.

With such structure, the joining area of the electrode 23 and peltier element 11 or 12 can be increased. Therefore, it is possible to increase the joining strength.

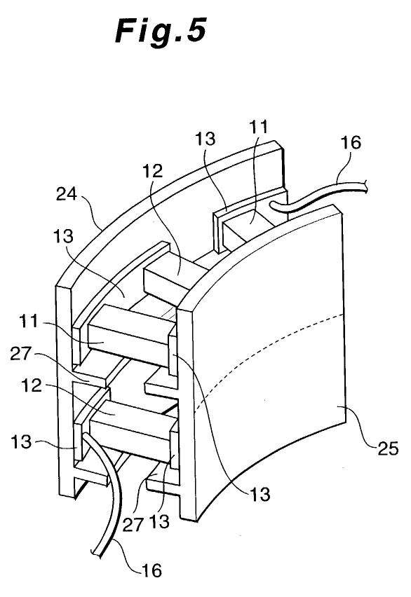

FIG. 5 is a squint-eyed diagram showing third embodiment of the present invention.

In the third embodiment, the level portion 23b as stated in second embodiment is removed and the supporting section 27 as stated in second embodiment is left. That is, the structure of the third embodiment is formed such as increasing the supporting section 27 on the foundation of the structure of the first embodiment.

Thus, the peltier element 11 or 12 is directly placed on the supporting section 27 and fixed by an adhesive or the like.

In the third embodiment, serving as the electrode, the electrode 13 stated in the first embodiment, but not the electrode 23 stated in the second embodiment is used. Thus, though no existing that such as the level portion 23b formed in the electrode 23 in the second embodiment, only because of the supporting section 27, it is sufficient to support the peltier element 11 or 12.

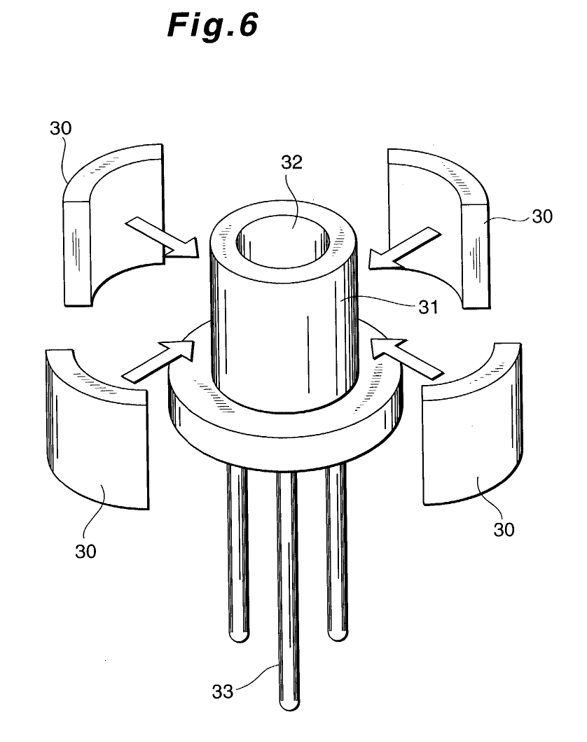

FIG. 6 is diagram illustrating an example applying a peltier cooler to a semiconductor laser module;

The semiconductor laser module is can type, is formed by sealing in airtight a semiconductor laser element, a receiving light element and an optical system into a metal package 31 with cylindrical type. In the semiconductor laser module, there are a laser light radiation opening 32 and leads 33.

Then, pluralities of, for example 4, the peltier coolers 30 of the present invention are installed on the outside surface of the metal package 31 by adhesive means as solder. Thus, the peltier cooler 30 of the present invention, because has the cylindrical curve surface, so can correspond with the outside surface of the metal package 31. Thereby, it is possible to not only easily perform the installing work but also improve the cooling efficiency.

Moreover, the four peltier coolers 30 are connected such as their poles join in series each other, the leads being anode or cathode formed on the end of the board are used as external use lead terminals.

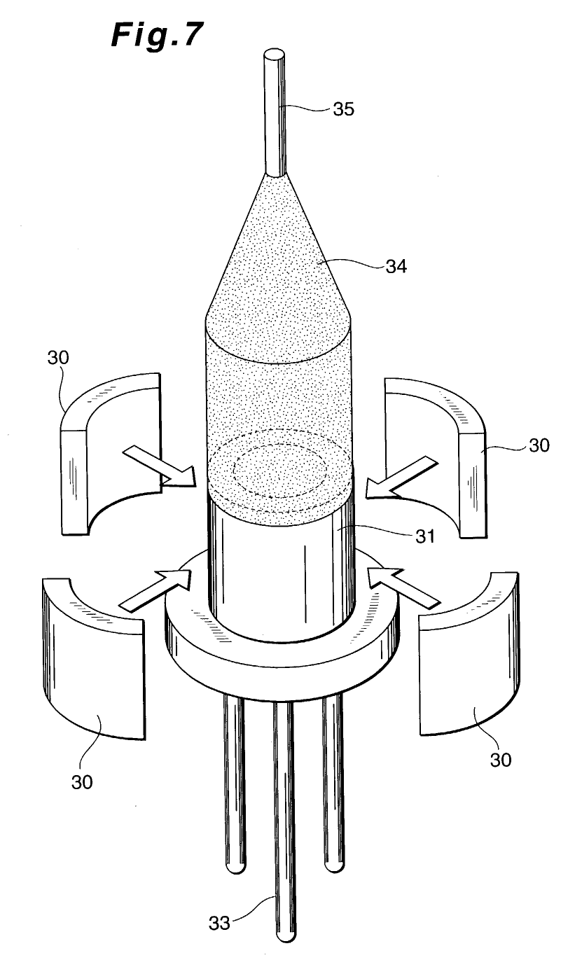

FIG. 7 is a diagram illustrating an example applying a peltier cooler of the present invention to a semiconductor laser module.

The semiconductor laser module is coaxial type, and is formed by connecting a optical fiber to a can type semiconductor laser module. In the FIG. 7, the semiconductor laser module includes a can type semiconductor laser module shown in FIG. 6, a rubber hood 34 and a optical fiber 35. In such semiconductor laser module, the installing work about installing the plural peltier coolers 30 on the outside surface of the metal package 31, as described above, is performed.

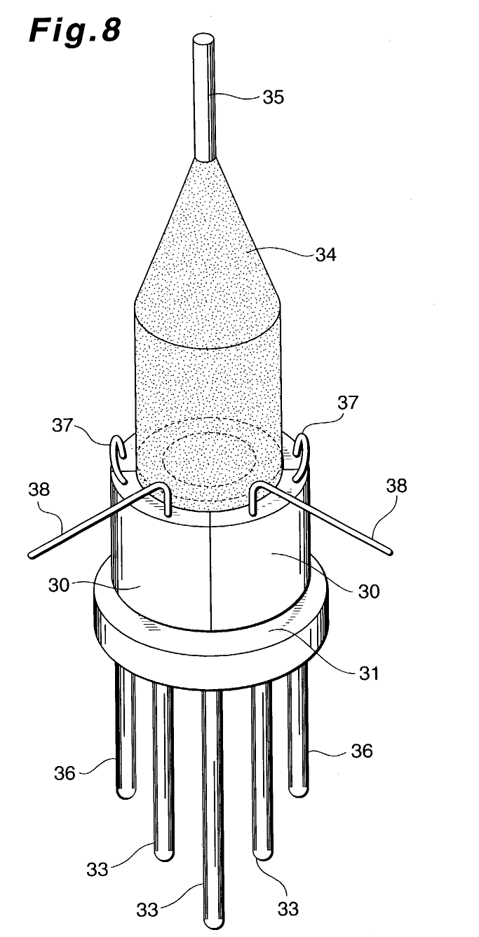

FIG. 8 is a diagram showing a installed state of the peltier cooler installed in a semiconductor laser module.

In the semiconductor laser module shown in FIG. 8, a themistor used for temperature control is placed in the metal package 31. Of course, it can be placed the outside of the package 31. Regarding its explanation, it is omitted in the examples shown by FIG. 6 and FIG. 7.

The themistor is used as a heating source, and is placed near the semiconductor laser element severing as an object of temperature control. Otherwise, the leads 36 is external connection use lead terminal.

Further, in the semiconductor laser module, the four peltier coolers 30 are connected each other in series by leads 37, the leads 38 at both ends is used as external connection use lead terminals.

Moreover, regarding the number of the peltier coolers 30, it may be optional according to necessary. If only closely installing these peltier coolers 30 on the outside surface such as ring shape, it is possible to demonstrate the cooling effect.

With the above stated, because the peltier cooler in the embodiments from first to third has the cylindrical curve surface, the peltier cooling can be applied to semiconductor laser module with cylindrical shape.

Further, in the first and second embodiments, because the supporting section is formed on the board for supporting the peltier element, the strength of the peltier cooler in itself can be improved.

In particular, in the second embodiment, the level portion is formed on the electrode and more fixed on the supporting section, the joined area of the peltier element and the electrode can be increased. Therefore, the joining strength of the peltier element and the electrode can be improved.

As an effect of the present invention, as described above, since the peltier cooler is formed with such shape having the cylindrical curve surface, it is possible to apply the peltier cooling to the semiconductor laser module with cylindrical shape for temperature control. Therefore, the semiconductor laser module with excellent cooling function and temperature control function can be supplied.

The present invention is not limited to the foregoing embodiments but many modifications and variations are possible within the spirit and scope of the appended claims of the invention.

What is claimed is:

1. A peltier cooler including:
a plurality of P type peltier elements;
a plurality of N type peltier elements;
a plurality of electrodes for connecting said P type peltier element and said N type peltier element;
two boards for sandwiching said P type peltier element and said N type peltier element;
wherein said board has cylindrical curve surface.

2. The peltier cooler according to claim 1, more including:
a plurality of supporting sections formed on said board for supporting said either of said P type peltier element, said N type peltier element.

3. The peltier cooler according to claim 2, more including:
a plurality of level portions formed on said electrode and fixed on said supporting section.

4. A semiconductor laser module including at least one peltier cooler, wherein the peltier cooler compeises:
a plurality of P type peltier elements;
a plurality of N type peltier elements;
a plurality of electrodes for connecting said P type peltier element and said N type peltier element;
two boards for sandwiching said P type peltier element and said N type peltier element; and
wherein said board has cylindrical curve surface.

5. The semiconductor laser module according to claim 4,
Wherein said peltier cooler more comprises:
a plurality of supporting sections formed on said board for supporting said either of said P type peltier element, said N type peltier element.

6. The semiconductor laser module according to claim 5,
Wherein said peltier cooler more comprises:
a plurality of level portions formed on said electrode and fixed on said supporting section.

7. The semiconductor laser module according to claim 4, more including a metal package, Wherein a plurality of said peltier coolers are installed and joined on the outside surface of said metal package.

8. The semiconductor laser module according to claim 7,
said semiconductor laser module is either of can type and coaxial type.
